(19) United States
(12) Patent Application Publication
(10) Pub. No.: US 2026/0344436 A1
(43) Pub. Date: Oct. 29, 2026

(54) SEAL RING STRUCTURE AND METHOD OF FORMING SAME

(71) Applicant: Taiwan Semiconductor Manufacturing Co., Ltd., Hsinchu (TW)

(72) Inventors: Sheng-Han Tsai, Hsinchu (TW); Tsung-Yu Chen, Hsinchu (TW); Hong-Yu Guo, Hsinchu (TW); Tsung-Shu Lin, New Taipei (TW); Hsin-Yu Pan, Taipei (TW)

(21) Appl. No.: 19/732,286

(22) Filed: Jul. 6, 2026

Related U.S. Application Data
(62) Division of application No. 18/510,523, filed on Nov. 15, 2023.
(60) Provisional application No. 63/513,365, filed on Jul. 13, 2023.

(51) Int. Cl. H10W 42/00; H10W 20/00; H10W 20/42; H10W 72/00; H10W 72/29; H10W 72/90; H10W 90/00

(52) U.S. Cl. CPC H10W 42/00; H10W 20/01; H10W 20/42; H10W 72/90; H10W 72/01908; H10W 72/29; H10W 72/936; H10W 90/792

(57) ABSTRACT

In an embodiment, a method includes: forming active devices over a semiconductor substrate; forming an interconnect structure over the active devices, the interconnect structure comprising a first portion of a seal ring over the semiconductor substrate, the seal ring being electrically insulated from the active devices; forming a first passivation layer over the interconnect structure; forming a first metal pad and a second metal pad extending through the first passivation layer and over the interconnect structure, the first metal pad having a bowl shape, the second metal pad having a step shape; and depositing a second passivation layer over the first metal pad and the second metal pad.

### PRIORITY CLAIM AND CROSS-REFERENCE

This application is a divisional of U.S. patent application Ser. No. 18/510,523 filed on Nov. 15, 2023, which application claims the benefit of the following provisionally filed U.S. Patent Application No. 63/513,365, filed on Jul. 13, 2023, which applications are hereby incorporated herein by reference.

### BACKGROUND

In wafer-level packaging technology, seal ring structures are formed in the peripheral region of the device dies, and used to provide protection to the circuits encircled by the seal rings. The seal ring may prevent moisture from penetrating into the device dies to degrade the circuits encircled by the seal rings. The seal rings may extend into multiple layers of integrated circuit structure such as low-k dielectric layers and the overlaying passivation layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 4A, 4B, 5A, 5B, 6A, 6B, 7A, 7B, 8A, and 8B illustrate cross-sectional views of intermediate stages in the formation of a device die including seal rings, in accordance with various embodiments.

FIGS. 6C, 7C, 8C illustrates a top view of a device die and seal rings therein, in accordance with various embodiments.

FIGS. 9, 10, 11, 12, 13, 14, and 15 illustrate cross-sectional views of intermediate stages in the formation of a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A seal ring of a package component (e.g., a semiconductor device or integrated circuit die) and the method of forming the same are provided. For example, active devices may be formed along a semiconductor substrate, an interconnect structure (e.g., metallization layers in low-k dielectric layers) may be formed over and electrically connected to the active devices, and a metal pad layer (e.g., metal pads in passivation layers). The active devices, the interconnect structure, and the metal pads are electrically connected features of an integrated circuit. In accordance with some embodiments of the present disclosure, the seal ring includes lower portions in the low-k dielectric layers, and an upper portion in a passivation layer. The lower portions of the seal ring may be formed simultaneously with the interconnect structure, and the upper portions of the seal ring may be formed simultaneously with the metal pad layer. In some embodiments, the seal ring forms a ring around the metallization layers and the metal pads of the integrated circuit. The upper portion of the seal ring may be located in high stress regions of the package component that are susceptible to cracking, delamination, or other types of damage during fabrication, testing, and/or functional use of an electronic device. Embodiments discussed herein provide examples for forming the seal ring (e.g., the upper portion of the seal ring) using the subject matter of this disclosure to reduce stress in these high stress regions. In addition, a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

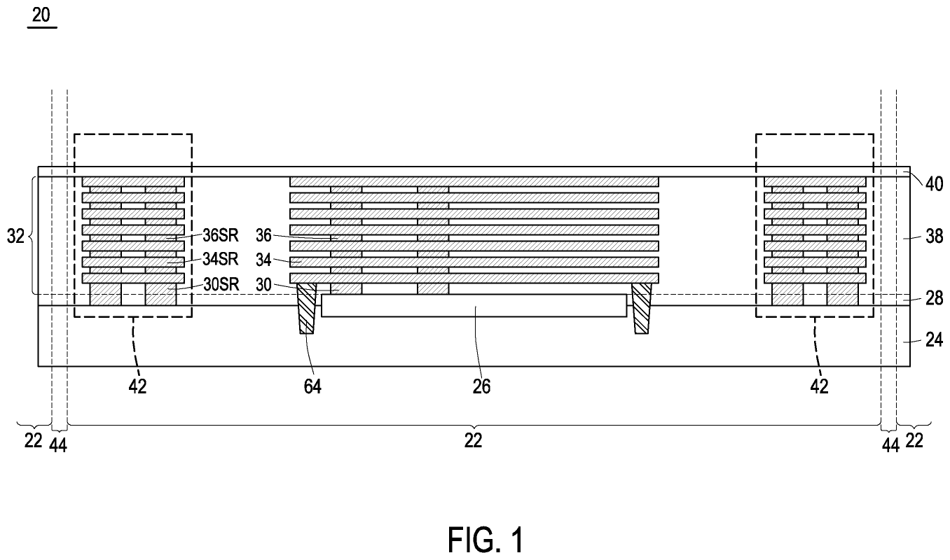

FIGS. 1 through 8C illustrate the cross-sectional and top views of intermediate stages in the formation of a device die and a seal ring therein, in accordance with some embodiments of the present disclosure. The corresponding processes are also reflected schematically in the process flow shown in FIG. 19.

FIG. 1 illustrates a cross-sectional view of package component 20. In accordance with some embodiments of the present disclosure, package component 20 is or comprises a device wafer including active devices and possibly passive devices, which are represented as integrated circuit devices 26. The corresponding package component 20 may include a plurality of integrated circuit dies or chips 22 therein, with one of chips 22 being illustrated. In accordance with alternative embodiments of the present disclosure, package component 20 is an interposer wafer, which is free from active devices, and may or may not include passive devices. In accordance with yet alternative embodiments, package component 20 is or comprises a package substrate strip, which includes a core-less package substrate or a cored package substrate with a core therein. In accordance with yet alternative embodiments of the present disclosure, package component 20 is a reconstructed wafer including discrete device dies and a molding compound molding the device dies therein. In subsequent discussion, a device wafer is used as an example of package component 20, and package component 20 may also be referred to as wafer 20. The embodiments of the present disclosure may also be applied on interposer wafers, package substrates, packages, etc.

In accordance with some embodiments of the present disclosure, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Semiconductor substrate 24 may also be a bulk semiconductor substrate or a Semiconductor-On-Insulator (SOI) substrate. Shallow Trench Isolation (STI) regions (not specifically illustrated) may be formed in semiconductor substrate 24 to isolate the active regions in semiconductor substrate 24. Although not shown, through-vias may (or may not) be formed to extend into semiconductor substrate 24, wherein the through-vias are used to electrically inter-couple the features on opposite sides of wafer 20.

In accordance with some embodiments of the present disclosure, wafer 20 includes integrated circuit devices 26, which are formed along the top surface (e.g., a front-side surface) of semiconductor substrate 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein. In accordance with alternative embodiments, wafer 20 is used for forming interposers (which are free from active devices), and substrate 24 may be a semiconductor substrate or a dielectric substrate.

Inter-Layer Dielectric (ILD) 28 is formed over semiconductor substrate 24 and fills the spaces between the gate stacks of transistors (not specifically illustrated) in integrated circuit devices 26. In accordance with some embodiments, ILD 28 is formed of or comprises Phospho Silicate Glass (PSG), Boro Silicate Glass (BSG), Boron-doped Phospho Silicate Glass (BPSG), Fluorine-doped Silicate Glass (FSG), silicon oxide, silicon nitride, silicon oxynitride (SiOₓN_{y}), low-k dielectric materials, or the like. ILD 28 may be formed using spin coating, Flowable Chemical Vapor Deposition (FCVD), Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments of the present disclosure, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Metal lines 34 and vias 36 are formed over ILD 28 and contact plugs 30. Contact plugs and the overlying metal lines and vias are collectively referred to as interconnect structure 32. Metal lines 34 and vias 36 are formed in dielectric layers 38 (also referred to as Inter-metal Dielectrics (IMDs)). The metal lines at a same level are collectively referred to as a metal layer hereinafter. In accordance with some embodiments of the present disclosure, interconnect structure 32 includes a plurality of metal layers including metal lines 34 that are interconnected through vias 36. The various layers of metal lines 34 and vias 36 may be collectively referred to as metallization layers. Metal lines 34 and vias 36 may be formed of copper or copper alloys, and they can also be formed of other metals. In accordance with some embodiments of the present disclosure, dielectric layers 38 are formed of low-k dielectric materials. The dielectric constants (k values) of the low-k dielectric materials may be lower than about 3.0, for example. Dielectric layers 38 may comprise carbon-containing low-k dielectric materials, Hydrogen SilsesQuioxane (HSQ), MethylSilsesQuioxane (MSQ), or the like. In accordance with some embodiments of the present disclosure, the formation of dielectric layers 38 includes depositing a porogen-containing dielectric material in the dielectric layers 38 and then performing a curing process to drive out the porogen, and hence the remaining dielectric layers 38 are porous.

The formation of metal lines 34 and vias 36 in dielectric layers 38 may include single damascene processes and/or dual damascene processes. In a single damascene process for forming a metal line or a via, a trench or a via opening is first formed in one of dielectric layers 38 (not separately illustrated), followed by filling the trench or the via opening with a conductive material. A planarization process such as a CMP process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

Metal lines 34 and vias 36 include top conductive (metal) features such as metal lines, metal pads, and/or vias in a top dielectric layer 38. In accordance with some embodiments, top dielectric layer 38 is formed of a low-k dielectric material similar to the material of lower ones of dielectric layers 38. In accordance with other embodiments, top dielectric layer 38 is formed of a non-low-k dielectric material, which may include silicon nitride, Undoped Silicate Glass (USG), silicon oxide, or the like. Top dielectric layer 38 may also have a multi-layer structure including, for example, two USG layers and a silicon nitride layer in between. Top metal features 34, 36 may also be formed of copper or a copper alloy, and may have a dual damascene structure or a single damascene structure.

Passivation layer 40 (sometimes referred to as passivation-1 or pass-1) is formed over interconnect structure 32. In accordance with some embodiments, passivation layer 40 is formed of a non-low-k and dense dielectric material having a dielectric constant equal to or greater than the dielectric constant of silicon oxide. Passivation layer 40 may be formed of or comprise an inorganic dielectric material, which may include a material selected from, and is not limited to, USG, silicon nitride (SiNₓ), silicon oxide (SiO₂), silicon oxy-nitride (SiONₓ), silicon oxy-carbide (SiOCₓ), or the like, combinations thereof, and/or multi-layers thereof. The value “x” represents the relative atomic ratio. In accordance with some embodiments, the top surfaces of top dielectric layer 38 and top metal lines 34 are coplanar. Accordingly, passivation layer 40 may be a planar layer. In accordance with alternative embodiments, the top conductive features protrude higher than the top surface of top dielectric layer 38, and passivation layer 40 is non-planar.

Package component 20 may further include through substrate vias (TSVs) 64 (or through vias) formed in semiconductor substrate 24 and electrically connected to, for example, metal lines 34 or vias 36 (e.g., metallization layers) of interconnect structure 32. As illustrated, through substrate vias 64 are embedded in semiconductor substrate 24 and interconnect structure 32, and through substrate vias 64 are not revealed from the back-side surface of semiconductor substrate 24 at this stage. Through substrate vias 64 may include Cu, Ti, Ta, W, Ru, Co, Ni, the like, an alloy thereof, or a combination thereof. In some embodiments, through substrate vias 64 are formed by an electroplating process and may comprise one or more layers (not separately illustrated), such as barrier layers, adhesion layers, fill material, and/or the like. In addition, a dielectric liner layer (not specifically illustrated) may separate through substrate vias 64 from semiconductor substrate 24.

Still referring to FIG. 1, lower portions of seal ring 42 include some contact plugs 30 (which are also denoted as 30SR), some metal lines 34 (which are also denoted as 34SR), and some vias 36 (which are also denoted as 36SR). Contact plugs 30SR, metal lines 34S, and vias 36SR are formed at the same time and share the same formation processes as the respective other contact plugs 30, metal lines 34, and vias 36 that are used for electrical connections of the integrated circuit. Each of contact plugs 30SR, metal lines 34SR, and vias 36SR in seal ring 42 may be physically joined with the overlying and underlying ones of these features to form an integrated seal ring. In addition, each of contact plugs 30SR, metal lines 34SR, and vias 36SR may form a full ring without break therein when viewed from top.

In accordance with some embodiments, contact plugs 30SR are electrically connected to semiconductor substrate 24. There may be (or may not be) silicide regions between and physically joining contact plugs 30SR and semiconductor substrate 24. In accordance with alternative embodiments, contact plugs 30SR are in physical contact with semiconductor substrate 24. In accordance with yet alternative embodiments, contact plugs 30SR are spaced apart from semiconductor substrate 24 by a dielectric layer such as a contact etch stop layer (underlying ILD 28, not shown), ILD 28, and/or the like.

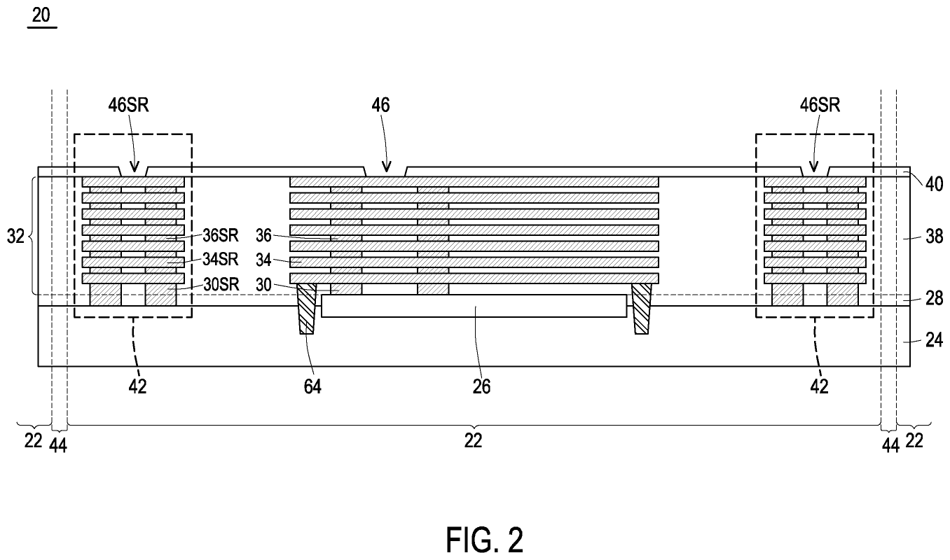

FIG. 2 illustrates patterning passivation layer 40 in an etching process to form openings 46. The etching process may include a dry etching process, which includes forming a patterned etching mask (not shown) such as a patterned photoresist, and then etching passivation layer 40. The patterned etching mask is then removed. Metal lines 34 are exposed through openings 46, and metal lines 34SR are exposed through openings 46SR.

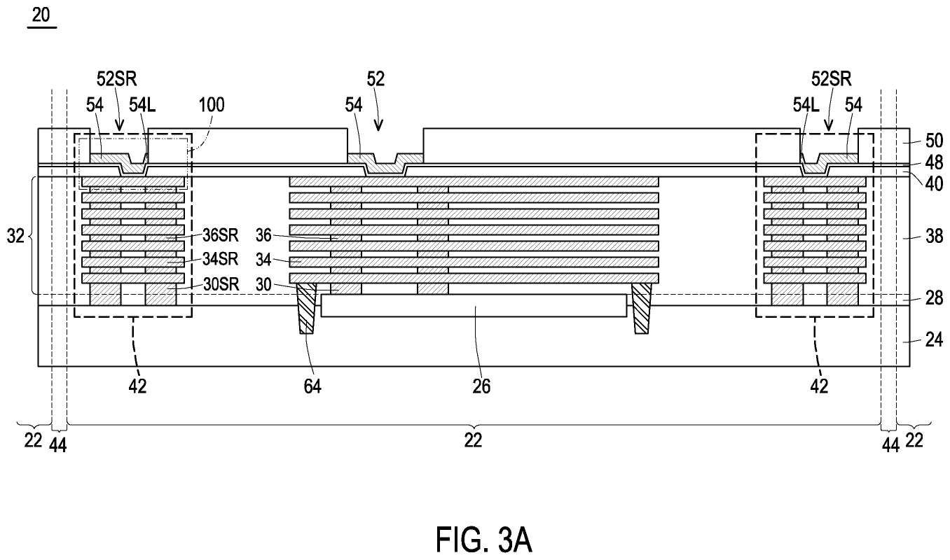

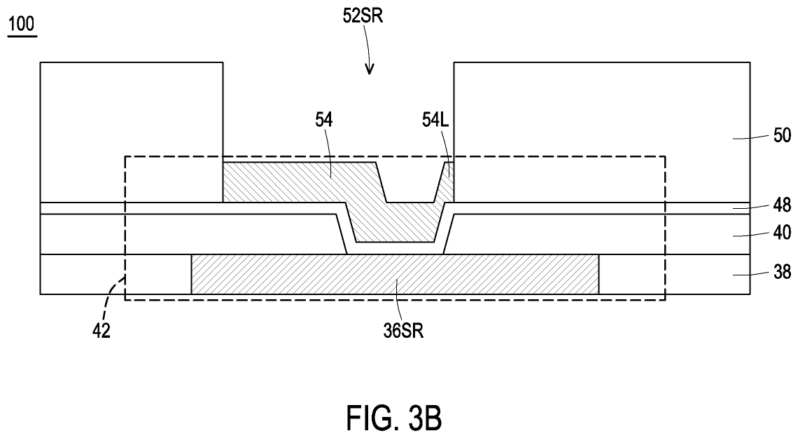

FIGS. 3A and 3B illustrate the deposition of metal seed layer 48 onto package component 20. FIG. 3B illustrates a zoomed-in view of region 100. In accordance with some embodiments, metal seed layer 48 comprises a titanium layer and a copper layer over the titanium layer. In accordance with alternative embodiments, metal seed layer 48 comprises a copper layer in contact with passivation layer 40. The deposition process may be performed using Physical Vapor Deposition (PVD), Chemical Vapor Deposition (CVD), Metal Organic Chemical Vapor Deposition (MOCVD), or the like.

Next, patterned plating mask 50 is formed. In accordance with some embodiments, plating mask 50 is formed of or comprises a photoresist. Openings 52 are formed in the patterned plating mask 50 to reveal metal seed layer 48.

Conductive material (features) 54 is then deposited in openings 52 and on metal seed layer 48. In accordance with some embodiments of the present disclosure, the formation of conductive material 54 includes a plating process, which may include an electrochemical plating process, an electroless plating process, or the like. The plating is performed in a plating chemical solution. Conductive material 54 may include copper, aluminum, nickel, tungsten, or the like, or alloys thereof. In accordance with some embodiments, conductive material 54 comprise copper, and are free from aluminum.

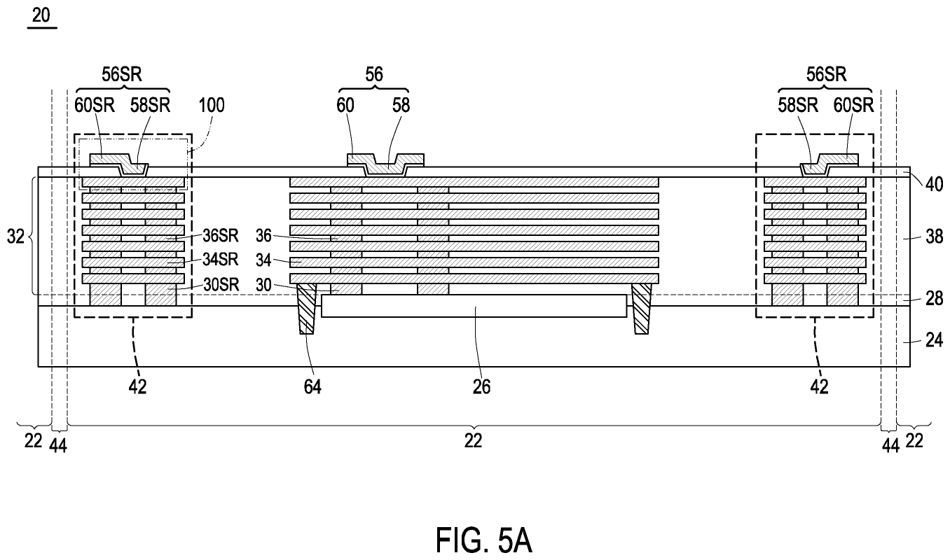

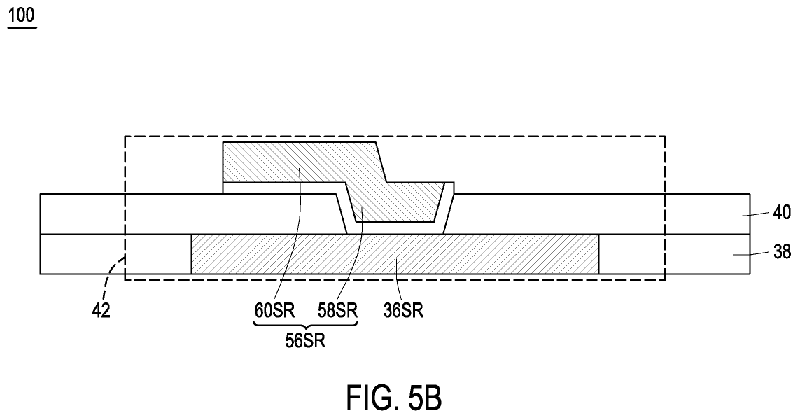

For example, plating mask 50 is formed to align with sidewalls of openings 46SR. As illustrated, plating mask 50 may be aligned with one sidewall of each opening 46SR. The resulting conductive material 54SR formed in openings 52SR may have a step-shape. In some embodiments (as illustrated), misalignment of plating mask 50 may result in conductive material 54SR having a lip 54L. Even if plating mask 50 is aligned, lip 54L may also form due to the sidewall of the opening 46SR having a slope less than vertical. As discussed in greater detail below, a subsequent processing step may be performed to remove lips 54L in order to give conductive material 54SR a desired step-shape. In other embodiments, lips 54L are not formed, and the resulting conductive material 54SR may be formed as illustrated in FIGS. 5A-5B and onward.

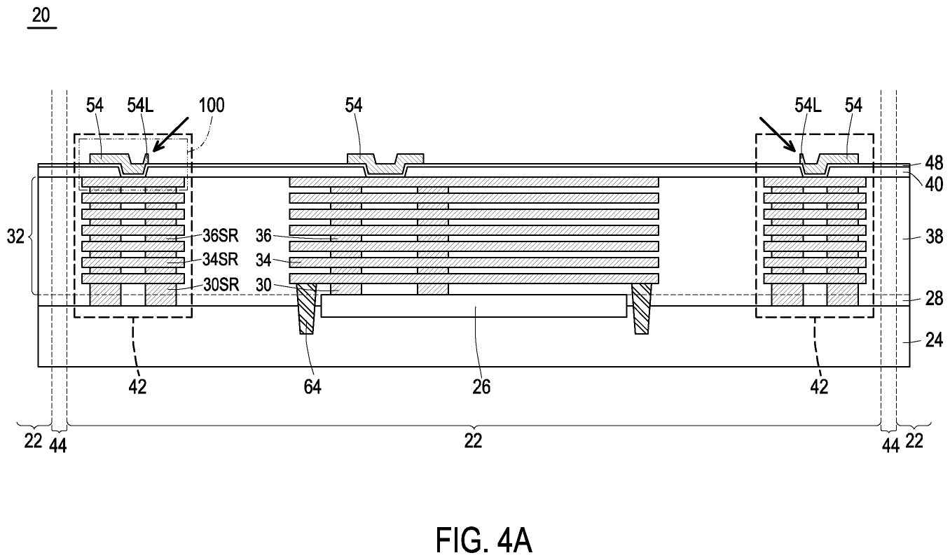

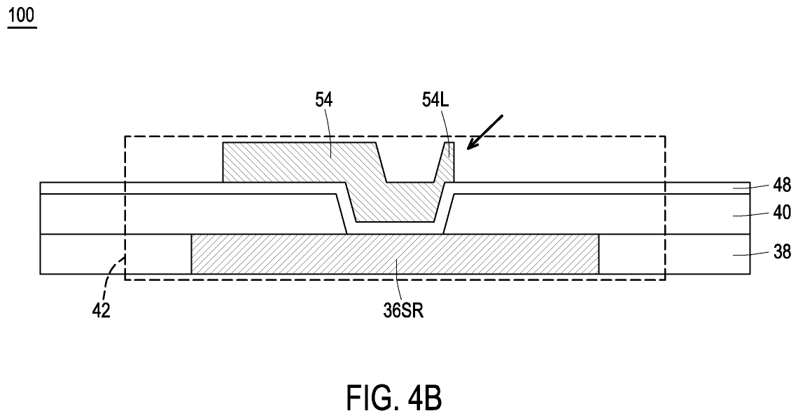

FIGS. 4A and 4B illustrate the resulting structure after removing plating mask 50, in accordance with various embodiments. FIG. 4B illustrates a zoomed-in view of region 100. In accordance with various embodiments, one or more directional (e.g., anisotropic) etching processes may be performed to remove lips 54L (if present) from conductive material 54SR. For example, the directional etching process may be a lateral directional etching process or any suitable etching process. In some embodiments, the etching processes include plasma or laser etching that is directed at lips 54L in order to avoid over-etching other portions of conductive material 54SR. FIG. 4B illustrates with dotted lines the result of removing the lips 54L. In some embodiments, the conductive material 54 (and the seed layer 48) may have a flat surface following removal of the lips 54L. In other embodiments, the conductive material (and the seed 48) may have a non-flat or uneven surface following removal of the lips 54L.

FIGS. 5A and 5B illustrate, after removing lips 54L (if necessary) from conductive material 54SR, performing an etching process to remove the portions of metal seed layers 48 that are no longer protected by the overlying conductive material 54. FIG. 5B illustrates a zoomed-in view of region 100. Throughout the description, the remaining conductive material 54 and the corresponding underlying portions of metal seed layer 48 are collectively referred to as metal pads 56, which include via portions 58 (also referred to as vias) extending into passivation layer 40, and pad portions 60 (also referred to as metal lines) over passivation layer 40. Some of metal pads 56 are used for electrical connection to interconnect structure 32. These metal pads 56 also include via portions 58 and pad portions 60, with the via portions 58 physically contacting top metal features 34.

Among metal pads 56 is metal pad ring 56SR which includes via ring 58SR and metal ring 60SR, which form an upper portion of seal ring 42. Via ring 58SR is in physical contact with the underlying metal line 34SR. In some embodiments, each of via ring 58SR and metal ring 60SR forms a full ring without break therein, and encircles an inner region of device die 22. As such, metal pad ring 56SR is electrically connected to the lower portions of seal ring 42 while being electrically insulated from interconnect structure 32 and integrated circuit device 26.

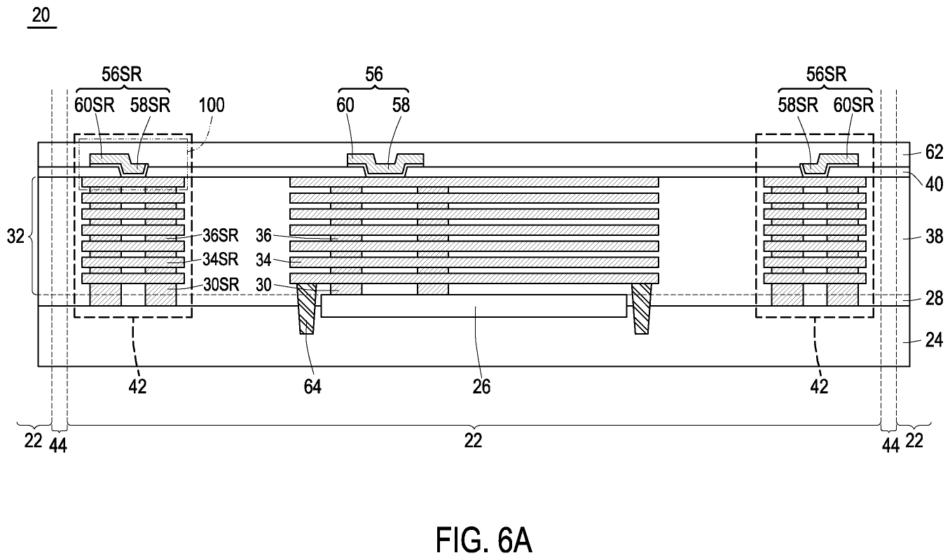

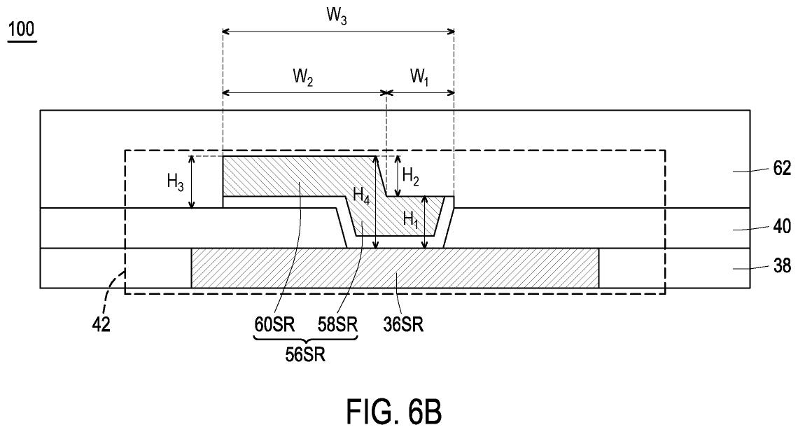

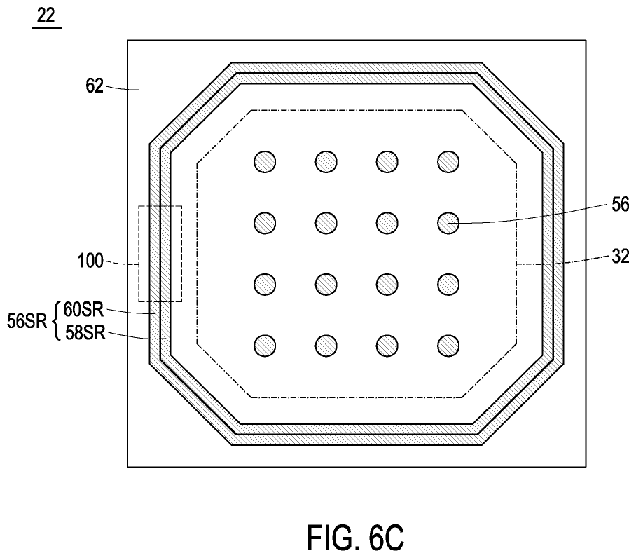

FIGS. 6A through 6C illustrate deposition of passivation layer 62. FIG. 6B illustrates a zoomed-in view of region 100, and FIG. 6C illustrates a plan view of chip 22. Passivation layer 62 (sometimes referred to as passivation-2 or pass-2) is formed as a blanket layer over metal pads 56. In accordance with some embodiments, passivation layer 62 is formed of or comprises an inorganic dielectric material, which may include, and is not limited to, silicon nitride, silicon oxide, silicon oxy-nitride, silicon oxy-carbide, or the like, combinations thereof, or multi-layers thereof. The material of passivation layer 62 may be the same or different from the material of passivation layer 40. The deposition may be performed through a conformal deposition process such as high density plasma CVD (HDP-CVD), ALD, CVD, or the like. In some embodiments, passivation layer 62 may be conformal with the vertical portions and horizontal portions having the same thickness or substantially the same thickness, for example, with a variation smaller than about 20 percent or 10 percent. In various embodiments, a planarization process is performed (such as a CMP process or a mechanical grinding process) to level the top surface of passivation layer 62. It is appreciated that regardless of whether passivation layer 62 is formed of a same material as passivation layer 40 or not, there may be a distinguishable interface, which may be visible, for example, in a Transmission Electron Microscopy (TEM) image, an X Ray Diffraction (XRD) image, or an Electron Back Scatter Diffraction (EBSD) image of the structure.

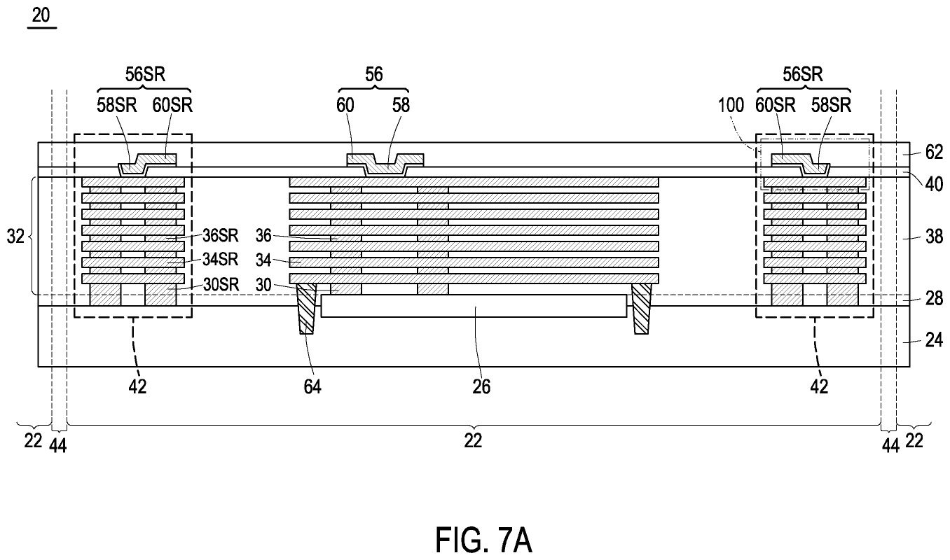

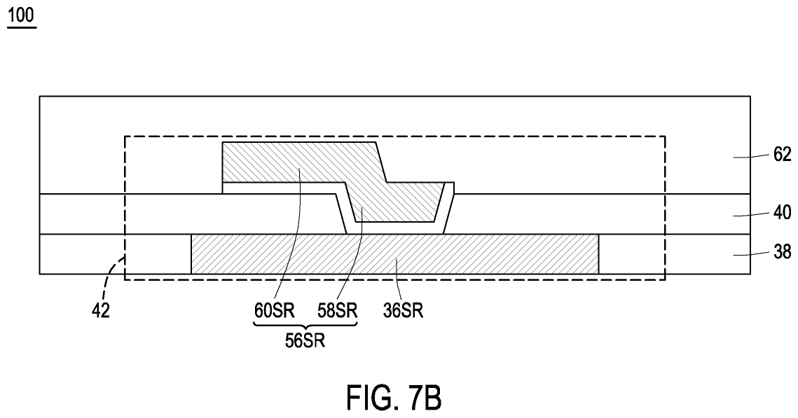

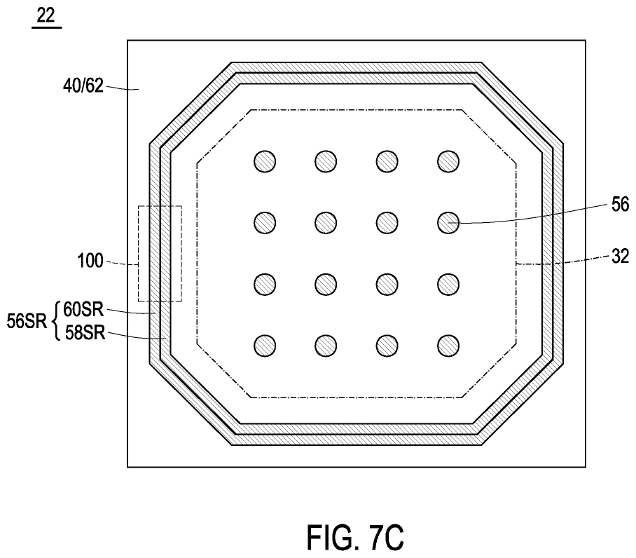

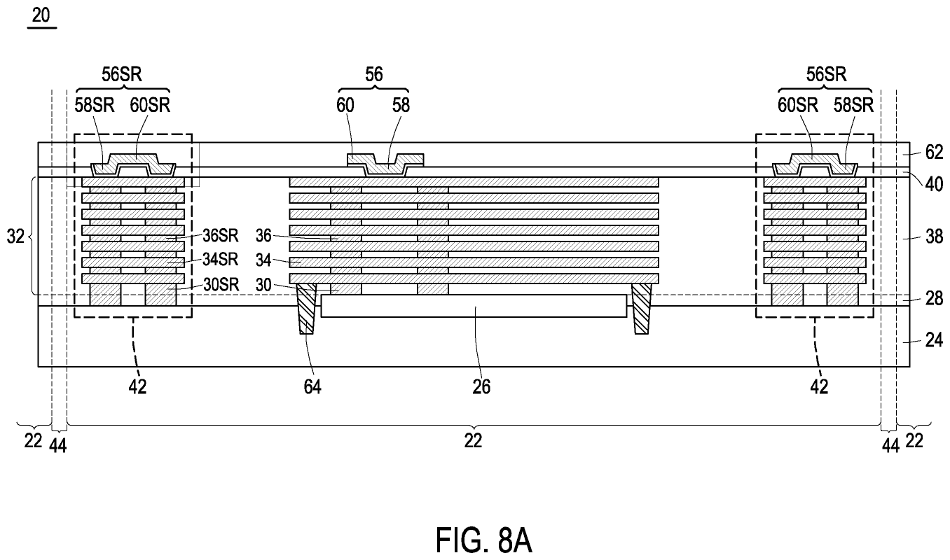

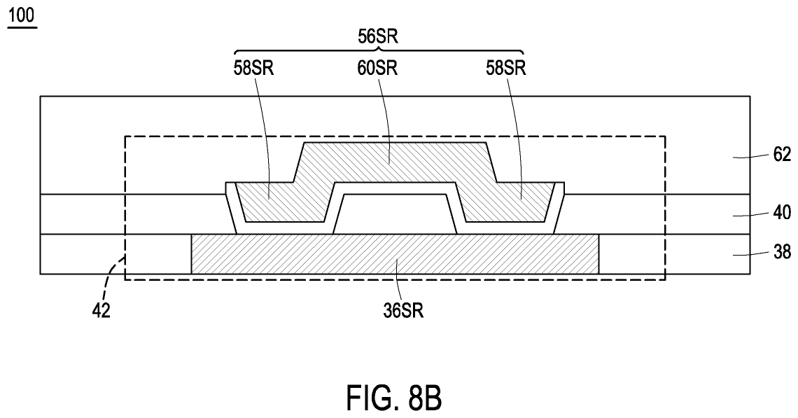

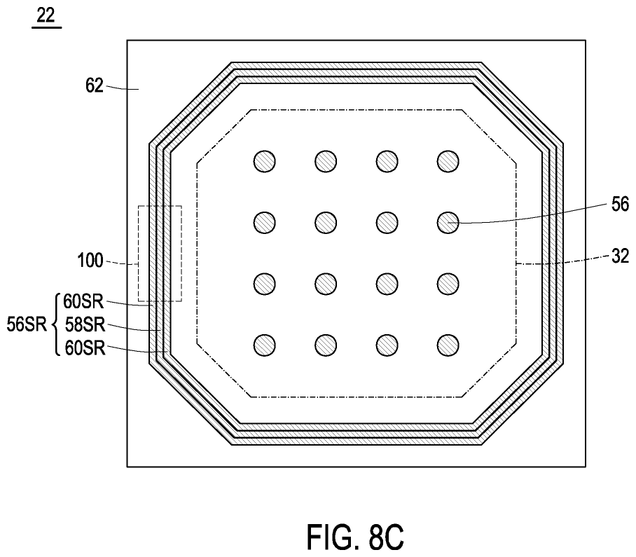

In various embodiments, metal pad 56SR may be formed with a step shape (e.g., a stair-step shape). For example, the stair-step shape may include a lower step (e.g., via portion 58SR) embedded in passivation layer 40 and an upper step (e.g., pad portion 60SR) embedded in passivation layer 62. As discussed in greater detail below, the stair-step shape of metal pad 56S may have an outward direction toward post-singulation sidewalls of device die 22 (as illustrated), an inward direction away from post-singulation sidewalls of device die 22 (see FIGS. 7A-7C), or a hill step comprising two lower steps and one upper step in the middle (see FIGS. 8A-C).

During various subsequent processes, regions of device die 22 near metal pad 56SR of seal ring 42 may experience high stress. As a result, passivation layer 62 in those regions may be susceptible to cracking, delamination, or other types of damage. Examples of such subsequent processes may include, but are not limited to, singulation of device dies 22 from wafer 24, bonding of package components 20 to a carrier, bonding of other package components to package components 20, testing of the completed or partially completed package, and singulation of the completed or partially completed package. In particular, the stress in these particular locations is reduced by the stair-step shape of metal pads 56SR as compared to a U-shape or a bowl shape. For example, the stair-step shape allows for deposition of the material of passivation layer 62 to be fill around metal pads 56SR without voids. In addition, the stair-step shape decreases the amount of the material of passivation layer 62 from residing within a nook or crevice of metal pad 56SR. As such, more of the material of passivation layer 62 is cohered to a bulk of passivation layer 62, which decreases the stress in those locations by up to about 60%.

Note that the various stair-step shapes of metal pad 56SR are different from metal pads 56 having a bowl shape or a U-shape in a cross-sectional view. Stresses tend to be lower near metal pads 56 as compared to metal pad 56SR. As a result, embodiments are described with respect to giving metal pad 56SR a stair-step shape while metal pads 56 are formed with a bowl shape or U-shape.

In accordance with various embodiments, the stair-step shape of metal pad 56SR may have dimensions in accordance with those labeled and discussed herein. In some embodiment, a width W₁ of the lower step may range from 1.8 μm to 3.2 μm, and a width W₂ of the upper step may range from 1.8 μm to 7.0 μm. For example, widths W₁ and W₂ may be substantially the same or different within the dimensions described above. A total width W₃ of metal pad 56SR may range from 3.6 μm to 10 μm. In addition, a height H₁ of the lower step may range from 0.5 μm to 1.5 μm, a height H₂ of the upper step above the lower step may range from 0.5 μm to 1.5 μm, and a height H₃ of the upper step above passivation layer 40 may range from 1.4 μm to 2.8 μm. A total height H₄ of metal pad 56SR may range from 1.0 μm to 3.0 μm. However, any suitable dimensions may be utilized. Widths and heights less than these upper bounds helps to decrease the amount that metal pad 56SR protrudes into passivation layer 62, thereby achieving the benefits described above. Widths and heights greater than these lower bounds improves effectiveness of seal ring 42 to protect the integrated circuit components disposed within device die 22.

FIG. 6C illustrates a top view of device die 22. As illustrated, metal pad 56SR of seal ring 42 encircles metal pads 56 without breaks (e.g., as a full ring), although breaks may be included in accordance with other embodiments. In addition, metal pad 56SR includes via portion 58SR and pad portion 60SR. Note that the illustrated edges represent the post-singulation sidewalls of chip 22.

FIGS. 7A through 7C illustrate other embodiments of package component 20, wherein metal pad 56SR has a stair-step shape with an inward direction away from post-singulation sidewalls of device die 22. As illustrated, similar or analogous dimensions may be utilized as described above in connection with FIGS. 6A-6C to achieve similar benefits. The illustrated embodiment may achieve additional benefits of the upper step (e.g., the pad portion) of metal pad 56SR being more distal from the post-singulation sidewalls. As a result, a greater stress reduction may be achieved. It should be appreciated that the embodiment illustrated in FIGS. 6A-6C may be preferable if metal pad 56SR has a close proximity to metal pads 56. As a result, less interference or parasitic capacitance may be achieved between metal pad 56SR and metal pads 56.

FIG. 7C illustrates a top view of device die 22. As illustrated, metal pad 56SR of seal ring 42 encircles metal pads 56 without breaks (e.g., as a full ring), although breaks may be included in accordance with other embodiments. In addition, metal pad 56SR includes via portion 58SR and pad portion 60SR. Note that the illustrated edges represent the post-singulation sidewalls of chip 22.

FIGS. 8A through 8C illustrate other embodiments of package component 20, wherein metal pad 56SR has a stair-step shape with a hill step of lower steps (e.g., via portions 58SR) on opposite sides of an upper step (e.g., pad portion 60SR). As illustrated, analogous dimensions may be utilized as described above in connection with FIGS. 6A-6C to achieve similar benefits. The illustrated embodiment may achieve additional benefits by having a stronger attachment within passivation layer 40, thereby further reducing the risk of delamination or other types of damage.

FIG. 8C illustrates a top view of device die 22. As illustrated, metal pad 56SR of seal ring 42 encircles metal pads 56 without breaks (e.g., as a full ring), although breaks may be included in accordance with other embodiments. In addition, metal pad 56SR includes via portion 58SR and pad portion 60SR. Note that the illustrated edges represent the post-singulation sidewalls of chip 22.

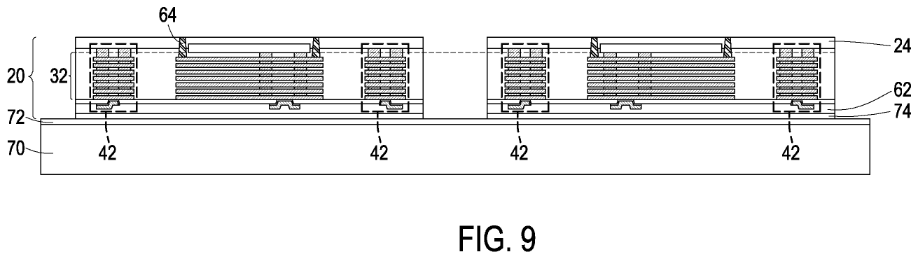

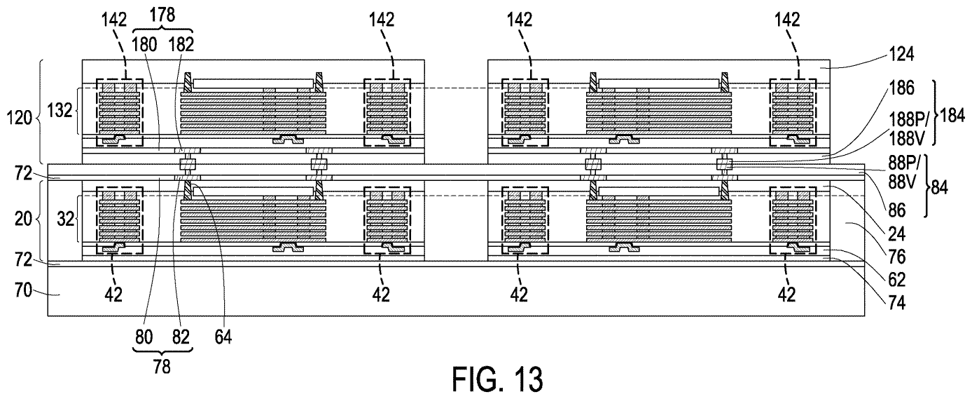

FIGS. 9 through 15 illustrate subsequent steps in attaching package components 20 to form a semiconductor package. Note that embodiments of package components described in FIGS. 6A-6C are illustrated. However, the embodiments of FIGS. 7A-7C and/or 8A-8C may also be used. For example, package components 120 are attached in FIG. 13, and package components 120 may also include seal rings 42 as described in any of the above embodiments. As such, package components 20 and 120 may be attached with any combination of embodiments of seal ring 42. In addition, although one layer of package components 20 and one layer of package components 120 are illustrated and described, any suitable number of layers may be utilized. In addition, any suitable combinations of embodiments of seal rings 42 may be utilized therein.

FIG. 9 illustrates a carrier 70 including a bonding film 72 thereon is provided. Carrier 70 may be a semiconductor wafer such as a silicon wafer, and bonding film 72 may be a bonding layer prepared for fusion bond. In some embodiments, bonding film 72 is a deposited layer formed over the top surface of carrier 70. In other embodiments, bonding film 72 is a portion of carrier 70 for fusion bond. In some embodiments, bonding film 72 includes silicon (Si), silicon oxide (SiOₓ, where x>0), silicon nitride (SiNₓ, where x>0), silicon oxynitride (SiOₓN_{y}, where x>0 and y>0) or other suitable bonding materials.

Package components 20 are attached to carrier 70. In some embodiments, passivation layer 62 of package component 20 is first covered by a bonding film 74. In some embodiments, bonding film 74 includes silicon (Si), silicon oxide (SiOₓ, where x>0), silicon nitride (SiNₓ, where x>0), silicon oxynitride (SiOₓN_{y}, where x>0 and y>0) or other suitable bonding materials. In some embodiments, bonding film 72 and bonding film 74 include the same material such as silicon oxide. In other embodiments, bonding film 72 and bonding film 74 include different materials. Package components 20 are then turned over and placed on carrier 70 such that bonding films 74 are in contact with bonding film 72. Specifically, multiple package components 20 are picked-up and placed on bonding film 72 in a side-by-side manner, such that package components 20 are arranged in array and spaced apart from each other. In some embodiments, each package component 20 is placed on the top surface of bonding film 72, such that front sides of package components 20 face bonding film 72 of carrier 70.

After package components 20 are picked up and placed on bonding film 72, a chip-to-wafer fusion bonding process may be performed such that a fusion bonding interface is formed between bonding film 72 and bonding film 74. For example, the fusion bonding process to bond bonding film 72 and bonding film 74 is performed at temperatures ranging from about 100 °C to about 290 °C Bonding film 72 may be directly bonded to bonding film 74. In other words, there is no intermediate layer formed between bonding film 72 and bonding film 74. The above-mentioned fusion bonding interface formed between bonding film 72 and bonding film 74 may be a Si—Si fusion bonding interface, a Si—SiOₓ fusion bonding interface, a SiOₓ—SiOₓ fusion bonding interface, a SiOₓ—SiNₓ fusion bonding interface or other suitable fusion bonding interface.

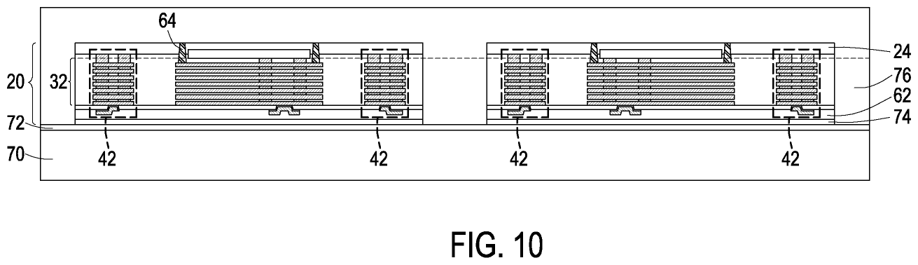

FIG. 10 illustrates that, after package components 20 are bonded to carrier 70 through bonding film 72 and bonding films 74, a dielectric encapsulation layer 76 is formed over carrier 70 and covers package components 20. In some embodiments, dielectric encapsulation layer 76 is formed by an over-molding process or a film deposition process such that a portion of the top surface of bonding film 72, side surfaces of bonding film 74, and back-side surfaces and side surfaces of package components 20 are encapsulated by dielectric encapsulation layer 76. In some embodiments, dielectric encapsulation layer 76 includes a molding compound, a molding underfill, a resin, combinations thereof, or the like. In some embodiments, dielectric encapsulation layer 76 includes a polymer material such as polybenzoxazole (PBO), polyimide, benzocyclobutene (BCB), a combination thereof, or the like. In some embodiments, dielectric encapsulation layer 76 includes an insulating material, such as silicon oxide, silicon nitride or a combination thereof.

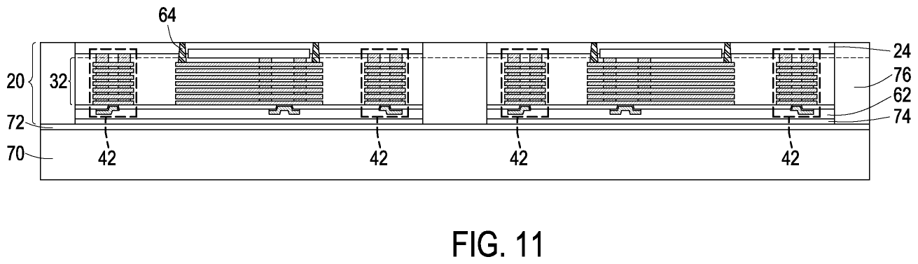

FIG. 11 illustrates that, after performing the over-molding process or film deposition process, a grinding process or a planarization process may be performed to reduce the thickness of dielectric encapsulation material 76 and the thickness of package components 20 until through substrate vias 64 are exposed. In some embodiments, the grinding process includes a mechanical grinding process, a CMP process, or a combination thereof.

In some embodiments, the thickness of package components 20 is equal to the thickness of dielectric encapsulation layer 76. In some embodiments, dielectric encapsulation layer 76 is in contact with the side surfaces of package components 20 and bonding films 74, and back surfaces of semiconductor substrates 24 are accessibly revealed through the thinned dielectric encapsulation layer 76. In other words, the top surface of dielectric encapsulation layer 76 is substantially level, within process variations, with the exposed surfaces of package components 20. However, the disclosure is not limited thereto. In some embodiments, the top surface of dielectric encapsulation layer 76 may be slightly higher than or slightly lower than the exposed surfaces of package components 20 due to polishing selectivity of the grinding process.

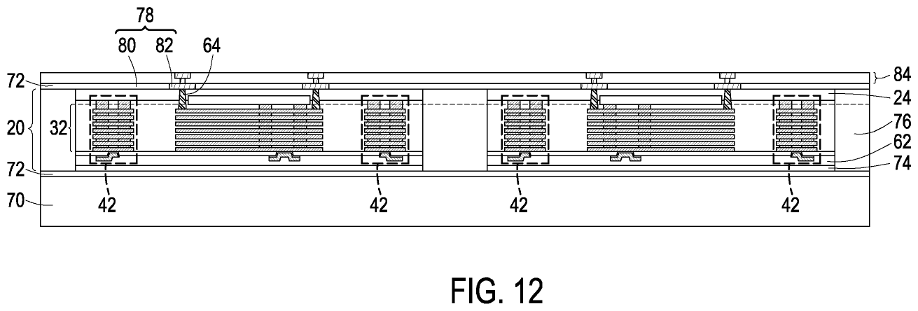

FIG. 12 illustrates that, a redistribution layer structure 78 is formed over the back-sides of package components 20 and the exposed surface of dielectric encapsulation layer 76. Redistribution layer structure 78 includes at least one polymer layer 80 and conductive features 82 embedded in polymer layer 80. Conductive features 82 include metal pads, metal lines and/or metal vias configured to electrically connect to different components. In some embodiments, polymer layer 80 includes a photo-sensitive material such as PBO, polyimide (PI), BCB, a combination thereof or the like. Polymer layer 80 of redistribution layer structure 78 may be replaced by a dielectric layer or an insulating layer as needed. In some embodiments, conductive features 82 may include Cu, Ti, Ta, W, Ru, Co, Ni, the like, an alloy thereof, a combination thereof, or the like. In some embodiments, a seed layer and/or a barrier layer may be disposed between each conductive feature 82 and polymer layer 80. The seed layer may include Ti/Cu. The barrier layer may include Ta, TaN, Ti, TiN, CoW, a combination thereof, or the like. The seed layer and the barrier layer may be considered part of conductive features 82.

In some embodiments, a bonding structure 84 is formed over redistribution layer structure 78. Bonding structure 84 is referred to a “blanket bonding structure” in some examples, because bonding structure 84 is formed across package components 20 and extends between and beyond package components 20. For example, bonding structure 84 may include at least one bonding film 86 and bonding metal features embedded in bonding film 86. In some embodiments, bonding film 86 includes an insulating material, a dielectric material, a polymer material or a combination thereof. For example, bonding film 86 includes silicon (Si), silicon oxide (SiOₓ, where x>0), silicon nitride (SiNₓ, where x>0), silicon oxynitride (SiOₓN_{y}, where x>0 and y>0) or other suitable bonding materials. The bonding metal features may include Cu, Ti, Ta, W, Ru, Co, Ni, an alloy thereof, a combination thereof, or the like. In some embodiments, a seed layer and/or a barrier layer may be disposed between each bonding metal feature and the bonding film 86. The seed layer may include Ti/Cu or any suitable material. The barrier layer may include Ta, TaN, Ti, TiN, CoW or a combination thereof. The seed layer and the barrier layer may be considered part of the bonding metal features.

In some embodiments, the bonding metal features include bonding pads 88P and bonding vias 88V. Bonding pads 88P and bonding vias 88V are configured to bond to and electrically connected to the underlying package components 20 and subsequently attached overlying package components. In some embodiments, bonding vias 88V are in physical contact with through substrate vias 64 and bonding pads 88P. In some embodiments, some bonding pads 88P are configured to bond to the underlying package components 20 and the subsequently attached overlying package components, but are electrically insulated from the package components 20 and the other package components. These such bonding pads 88P are referred to as “dummy bonding pads” or “floating bonding pads” in some examples because they are provided to merely enhance the bonding strength between package components.

FIG. 13 illustrates placing package components 120 (e.g., memory dies, logic dies or other suitable dies) on bonding structures 84. Although two package components 120 are illustrated as being attached to two package components 20, the numbers of package components 20, 120 are not limited by the illustration. In some embodiments, package components 120 correspond to underlying package components 20, respectively. Package components 120 and package components 20 may be the same type or different types of dies.

As illustrated, package components 120 may be formed similarly and contain similar features as described above in connection with package components 20. Same features may be labeled as the same numbers but starting with a “1” in the hundreds place. For example, similarly as package components 20, package components 120 may include integrated circuit devices 126 formed along a front-side of a semiconductor substrate 124, an interconnect structure 132 formed over the integrated circuit devices 126, and metal pads 156 formed over and electrically connected to the interconnect structure 132. Interconnect structure 132 includes metal lines 134 and vias 136. Seal rings 142 may be formed simultaneously with interconnect structure 132 and metal pads 156. For example, seal ring 142 may include metal lines 134SR, vias 136SR, and metal pads 156SR which may be electrically connected to one another, similarly as metal lines 34SR, vias 36S, and metal pads 56SR of package components 20. As such, metal lines 134SR, vias 136SR, and metal pads 156SR collectively form seal ring 42 for package component 120. Further, passivation layer 140 and passivation layer 162 are disposed over and around metal pads 156, similarly as passivation layer 40 and passivation layer 62, respectively, of package components 20.

In some embodiments, a redistribution layer structure 178 may be disposed over passivation layer 162 and electrically connected to metal pads 156. Redistribution layer structure 178 may be formed similarly and include similar features as redistribution layer structure 78 formed over package component 20. For example, redistribution layer structure 178 may include conductive features 182 embedded in at least one polymer layer 180. Conductive features 182 include metal pads, metal lines and/or metal vias configured to electrically connect to different components.

In addition, a bonding structure 184 may be disposed over metal pads 156 and over redistribution layer structure 178 (if present). Bonding structure 184 may be electrically connected to metal pads 156 directly, through the redistribution layer, or a combination thereof. Bonding structure 184 may be formed similarly as bonding structure 84, such as being formed as a blanket bonding structure over a wafer before singulating individual package components 120. Bonding structure 184 may include bonding metal features extending through at least one bonding film 186. The bonding metal features may include bonding pads 188P and bonding vias 188V. Bonding pads 188P and bonding vias 188V are configured to bond and electrically connect to underlying electrical features of package components 120. Some of bonding pads 188P may be dummy bonding pads or floating bonding pads to enhance bonding strength with bonding pads 88P along package components 20.

In some embodiments, to facilitate chip-to-wafer direct bonding between bonding structure 84 and bonding structure 184, surface preparation for bonding surfaces of bonding structure 84 and bonding structure 184 is performed. The surface preparation may include surface cleaning and activation, for example. Surface cleaning may be performed on the bonding surfaces of bonding structure 84 and bonding structure 184 to remove particles and/or native oxides on bonding surfaces of the respective bonding pads and bonding films. The bonding surfaces of bonding structure 84 and bonding structure 184 are cleaned by wet cleaning, for example.

After cleaning the bonding surfaces of bonding structures 84 and bonding structure 184, activation of the top surfaces may be performed for development of high bonding strength. In some embodiments, plasma activation is performed to treat and activate the bonding surfaces of bonding films 86 and 186. When the activated bonding surface of bonding film 86 is in contact with the activated bonding surface of bonding film 186, bonding films 86 and 186 are pre-bonded. Bonding structure 184 and bonding structure 84 are pre-bonded through a pre-bonding of bonding films 86 and 186. After the pre-bonding of bonding films 86 and 186, bonding pads 88P are in contact with bonding pads 188P.

After the pre-bonding process of bonding films 86 and 186, a dielectric-to-dielectric and metal-to-metal direct bonding of package component 120 with bonding structure 84 is performed. The direct bonding of package component 120 and bonding structure 84 may include a treatment for dielectric bonding and a thermal annealing for metal bonding. The treatment for dielectric bonding is performed to strengthen the bonding between bonding films 86 and 186. The treatment for dielectric bonding may be performed at temperatures ranging from about 100 °C to about 150 °C, for example. After performing the treatment for dielectric bonding, the thermal annealing for metal bonding is performed to facilitate the bonding between bonding pads 88P and 188P. The thermal annealing for metal bonding may be performed at temperatures ranging from about 300 °C to about 400 °C, for example. The process temperature of the thermal annealing for metal bonding is higher than that of the treatment for dielectric bonding. Since the thermal annealing for metal bonding is performed at relative higher temperature, metal diffusion and grain growth may occur at bonding interfaces between bonding pads 88P and 188P. The metal bonding is not limited to the pad-to-pad bonding. Via-to-via bonding or via-to-pad bonding may be applied as needed.

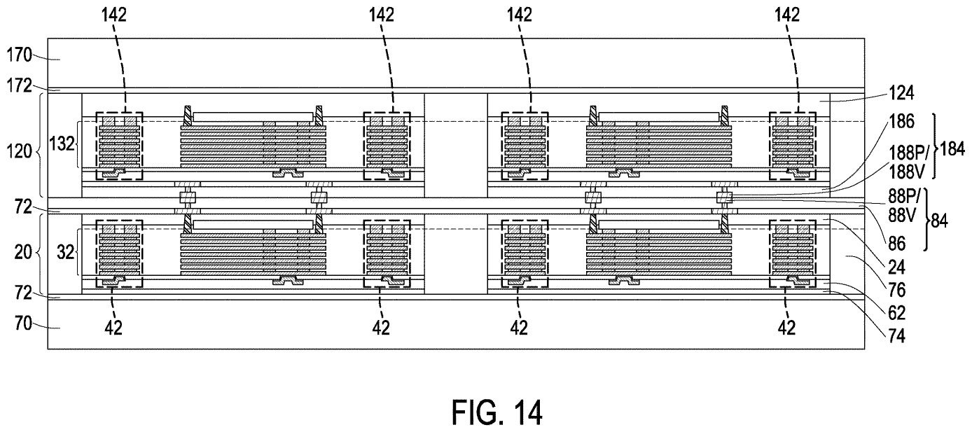

FIG. 14 illustrates, after package components 120 are bonded to package components 20 through bonding structure 84 and bonding structure 184, a dielectric encapsulation layer 176 is formed to cover bonding structure 84 and package components 120. In some embodiments, dielectric encapsulation layer 176 is formed by an over-molding process or a film deposition process such that a portion of the top surface of bonding structure 84, side surfaces of bonding structures 184, and back-side surfaces and side surfaces of package components 120 are encapsulated by dielectric encapsulation layer 176. In some embodiments, dielectric encapsulation layer 176 includes a molding compound, a molding underfill, a resin or the like. In some embodiments, dielectric encapsulation layer 176 includes a polymer material (such as PBO, polyimide, BCB, a combination thereof, or the like), an insulating material (such as silicon oxide, silicon nitride, a combination thereof, or the like), combinations thereof, or the like.

After performing the over-molding process or film deposition process, a grinding process or a planarization process may be performed to reduce the thickness of the encapsulation material and the thickness of package components 120 until the back-side surfaces of package components 120 are exposed. In some embodiments, the grinding process includes a mechanical grinding process, a CMP process, or a combination thereof.

Still referring to FIG. 14, a carrier 170 including a bonding film 172 thereon is attached. Carrier 170 may be a glass wafer, and bonding film 172 may be an adhesive material. Bonding film 172 may include an oxide layer, a die attach tape (DAF) or a suitable adhesive. Carrier 170 is bonded to the back-side surfaces of package components 120 and the exposed surface of dielectric encapsulation layer 176 through bonding film 172. In some embodiments (not specifically illustrated), a blanket bonding film may be provided between bonding film 172 and semiconductor substrate 224 and between bonding film 172 and dielectric encapsulation layer 176, and bonding film 172 may be bonded to the blanket bonding film through a fusion bond.

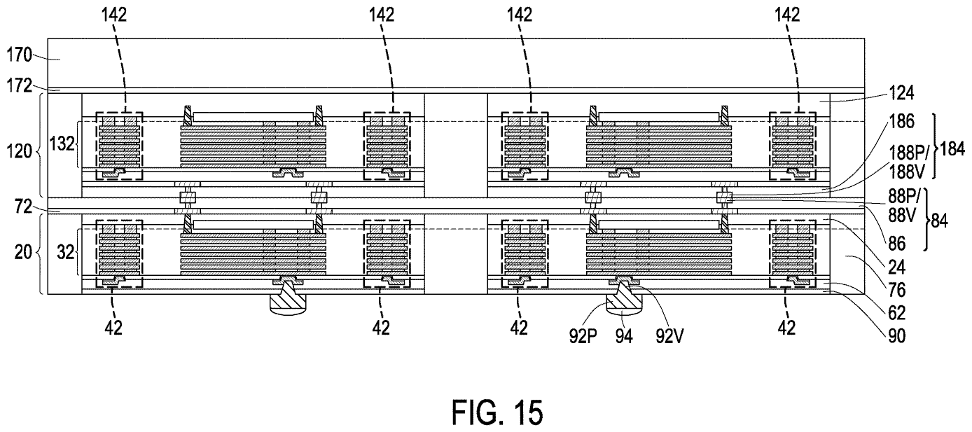

FIG. 15 illustrates a de-bonding process which may be performed to de-bond bonding film 72 and underlying carrier 70 from bonding films 74 and from dielectric encapsulation layer 76. The de-bonding process may be a laser lift-off process or other suitable de-bonding processes. After removing bonding film 72 and carrier 70, a grinding process may be performed such that bonding films 74 and dielectric encapsulation layer 76 are thinned. In some embodiments, bonding films 74 may be removed to expose passivation layer 62. During the removal of bonding films 74, dielectric encapsulation layer 76 may be thinned down. In some embodiments, the removal of bonding films 74 and the thinning of dielectric encapsulation layer 76 may be performed by the same grinding process (e.g., a CMP process). After performing the grinding process, package components 20 are revealed, but metal pads 56 of package components 20 are not revealed and remain covered by passivation layer 62 at this stage.

In accordance with various embodiments, a patterning process of passivation layer 62 is then performed, such that openings are formed in passivation layer 62 to expose metal pads 56. In some embodiments, a post passivation layer 90 is first formed to cover dielectric encapsulation layer 76 and passivation layer 62 of package components 20, and the openings are formed through post passivation layer 90 as well as passivation layer 62. In some embodiments, photolithography and etching processes are performed to form the openings. However, the disclosure is not limited thereto. In other embodiments, a laser drilling process is performed to form the openings.

FIG. 15 illustrates the formation of electrical connectors 94 and vias 92. In accordance with some embodiments, the formation process includes depositing a blanket metal seed layer (not shown) extending into the openings in post passivation layer 90 and passivation layer 62, forming a patterned plating mask, and plating a conductive material into the openings in the plating mask. In accordance with some embodiments, the metal seed layer includes a titanium layer and a copper layer over the titanium layer. Alternatively, the metal seed layer is a single copper layer. The plated conductive material may comprise copper, nickel, palladium, aluminum, lead-free solder, alloys thereof, and/or multi-layers thereof. The plating mask is then removed, followed by an etching process to remove the portions of the metal seed layer not covered by the plated conductive material, thus forming vias 92V and electrical connectors 94. For example, electrical connectors 94 may include metal pillars 92P and solder regions 94. A reflow process is performed to reflow solder regions 94. In some embodiments, the electrical connectors 94 may be micro bumps or controlled collapse of chip connection (C4) Bumps.

The embodiments of the present disclosure have some advantageous features. By forming seal rings 42 with metal pads 56SR having stair-step shapes, stresses in locations of device dies 22 near metal pads 56SR may be reduced. In addition, quality of passivation layer 62 may be improved for greater fabrication yield and performance of resulting semiconductor packages.

In an embodiment, a method includes: forming active devices over a semiconductor substrate; forming an interconnect structure over the active devices, the interconnect structure comprising a first portion of a seal ring over the semiconductor substrate, the seal ring being electrically insulated from the active devices; forming a first passivation layer over the interconnect structure; forming a first metal pad and a second metal pad extending through the first passivation layer and over the interconnect structure, the first metal pad having a bowl shape, the second metal pad having a step shape; and depositing a second passivation layer over the first metal pad and the second metal pad. In another embodiment, the first metal pad is electrically connected to the active devices. In another embodiment, the second metal pad is a second portion of the seal ring. In another embodiment, the step shape of the second metal pad comprises a lower step embedded in the first passivation layer and an upper step along a major surface of the first passivation layer. In another embodiment, the upper step is more proximal than the lower step to the first metal pad. In another embodiment, the lower step is more proximal than the upper step to the first metal pad. In another embodiment, the step shape of the second metal pad comprises an additional lower step embedded in the first passivation layer, and wherein the upper step is laterally interposed between the lower step and the additional lower step. In another embodiment, the semiconductor substrate comprises a wafer, wherein the method further comprises: attaching a carrier substrate to the second passivation layer; attaching a package component to a back-side of the semiconductor substrate, the package component being electrically connected to the active devices; removing the carrier substrate; and forming an electrical connector over the second passivation layer and electrically connected to the first metal pad.

In an embodiment, semiconductor device includes: a first package component comprising: a first passivation layer; an electrical connector extending through the first passivation layer; a second passivation layer over the first passivation layer; a first metal pad and a second metal pad embedded in the first passivation layer and the second passivation layer, the first metal pad comprising a first U-shape, the second metal pad having a first stair-step shape; a first plurality of dielectric layers over the second passivation layer; a first plurality of metallization layers and a second plurality of metallization layers embedded in the first plurality of dielectric layers, the second metal pad and the second plurality of metallization layers being electrically insulated from the first metal pad and the first plurality of metallization layers; and an active device over and electrically connected to the first plurality of metallization layers. In another embodiment, the first metal pad is electrically connected to the electrical connector. In another embodiment, the first stair-step shape of the second metal pad comprises a first step and a second step, wherein the first step is embedded in the first passivation layer and the second passivation layer, and wherein the second step is embedded in the second passivation layer. In another embodiment, the semiconductor device further includes a second package component, the second package component comprising: a bond film attaching the second package component to the first package component; a bond pad embedded in the bond film; a third passivation layer over the bond film; a fourth passivation layer over the third passivation layer; a third metal pad and a fourth metal pad embedded in the third passivation layer and the fourth passivation layer, the third metal pad comprising a second U-shape, the fourth metal pad having a second stair-step shape; a second plurality of dielectric layers over the fourth passivation layer; and a third plurality of metallization layers and a fourth plurality of metallization layers embedded in the second plurality of dielectric layers, the fourth metal pad and the fourth plurality of metallization layers being electrically insulated from the third metal pad and the third plurality of metallization layers. In another embodiment, the first stair-step shape and the second stair-step shape have a same direction. In another embodiment, the first stair-step shape and the second stair-step shape have different directions.

In an embodiment, semiconductor device includes: an active device formed along a front-side of a semiconductor substrate; first dielectric layers over the semiconductor substrate; first metallization layers within the first dielectric layers, the first metallization layers forming an interconnect structure; second metallization layers within the first dielectric layers, the second metallization layers forming a ring around the first metallization layers; a first metal pad over and electrically connected to the first metallization layers, in a cross-section the first metal pad comprising a U-shape with a left arm and a right arm; a second metal pad over and electrically connected to the second metallization layers, the second metal pad forming a ring around the first metal pad, in the cross-section the second metal pad comprising a left portion adjacent to the left arm and a right portion adjacent to the right arm, the left portion having a first stair-step shape, the right portion having a second stair-step shape, the first stair-step shape being a reflection of the second stair-step shape, the U-shape being different from the first stair-step shape and the second stair-step shape; and second dielectric layers over the first dielectric layers and encapsulating the first metal pad and the second metal pad. In another embodiment, the first stair-step shape of the left portion has the same direction as the left arm of the U-shape, and wherein the second stair-step shape of the right portion has the same direction as the right arm of the U-shape. In another embodiment, the first stair-step shape of the left portion has the same direction as the right arm of the U-shape, and wherein the second stair-step shape of the right portion has the same direction as the left arm of the U-shape. In another embodiment, each of the first stair-step shape and the second stair-step shape are hill steps. In another embodiment, the semiconductor device further includes an electrical connector over and extending through the second dielectric layers, wherein the electrical connector is electrically connected to the first metal pad. In another embodiment, the semiconductor device further includes: a through via extending from the front-side to a back-side of the semiconductor substrate; and an integrated circuit die attached to the semiconductor substrate and electrically connected to the through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first package component comprising:
a first passivation layer;
an electrical connector extending through the first passivation layer;
a second passivation layer over the first passivation layer;
a first metal pad and a second metal pad embedded in the first passivation layer and the second passivation layer, the first metal pad comprising a first U-shape, the second metal pad comprising a first stair-step shape;
a first plurality of dielectric layers over the second passivation layer;
a first plurality of metallization layers and a second plurality of metallization layers embedded in the first plurality of dielectric layers, the second metal pad and the second plurality of metallization layers being electrically insulated from the first metal pad and the first plurality of metallization layers; and
an active device over and electrically connected to the first plurality of metallization layers.

2. The semiconductor device of claim 1, wherein the second metal pad and the second plurality of metallization layers are electrically connected to each other, and wherein the second metal pad and the second plurality of metallization layers form a seal ring encircling the first metal pad and the first plurality of metallization layers.

3. The semiconductor device of claim 1, wherein the first metal pad is electrically connected to the electrical connector.

4. The semiconductor device of claim 1, wherein the first stair-step shape of the second metal pad comprises a first step and a second step, wherein the first step is embedded in the first passivation layer and the second passivation layer, and wherein the second step is embedded in the first passivation layer and interfaces with a surface of the second passivation layer.

5. The semiconductor device of claim 4, wherein the first passivation layer and the second passivation layer meet at an interface, wherein a surface of the first step is located past the interface and within the first passivation layer, and wherein the second step is disposed along the interface.

6. The semiconductor device of claim 1, further comprising a second package component over the first package component, wherein a front side of the second package component is bonded to a back side of the first package component, the second package component comprising:
a bond film attaching the second package component to the first package component;
a bond pad embedded in the bond film;
a third passivation layer over the bond film;
a fourth passivation layer over the third passivation layer;
a third metal pad and a fourth metal pad embedded in the third passivation layer and the fourth passivation layer, the third metal pad comprising a second U-shape, the fourth metal pad comprising a second stair-step shape;
a second plurality of dielectric layers over the fourth passivation layer; and
a third plurality of metallization layers and a fourth plurality of metallization layers embedded in the second plurality of dielectric layers, the fourth metal pad and the fourth plurality of metallization layers being electrically insulated from the third metal pad and the third plurality of metallization layers.

7. The semiconductor device of claim 6, wherein the first stair-step shape and the second stair-step shape have a same direction.

8. The semiconductor device of claim 6, wherein the first stair-step shape and the second stair-step shape have different directions.

9. A semiconductor device comprising:
an active device formed along a front-side of a semiconductor substrate;
first dielectric layers over the semiconductor substrate;
first metallization layers within the first dielectric layers, the first metallization layers forming an interconnect structure;
second metallization layers within the first dielectric layers, the second metallization layers forming a ring around the first metallization layers;
a first metal pad over and electrically connected to the first metallization layers, in a cross-section the first metal pad comprising a U-shape with a left arm and a right arm;
a second metal pad over and electrically connected to the second metallization layers, the second metal pad forming a ring around the first metal pad, in the cross-section the second metal pad comprising a left portion adjacent to the left arm and a right portion adjacent to the right arm, the left portion comprising a first stair-step shape, the right portion comprising a second stair-step shape, the first stair-step shape being a reflection of the second stair-step shape, the U-shape being different from the first stair-step shape and the second stair-step shape; and
second dielectric layers over the first dielectric layers and encapsulating the first metal pad and the second metal pad.

10. The semiconductor device of claim 9, wherein the first stair-step shape of the left portion has the same direction as the left arm of the U-shape, and wherein the second stair-step shape of the right portion has the same direction as the right arm of the U-shape.

11. The semiconductor device of claim 9, wherein the first stair-step shape of the left portion has the same direction as the right arm of the U-shape, and wherein the second stair-step shape of the right portion has the same direction as the left arm of the U-shape.

12. The semiconductor device of claim 9, wherein the first stair-step shape and the second stair-step shape comprise hill steps.

13. The semiconductor device of claim 9, further comprising an electrical connector over and extending through the second dielectric layers, wherein the electrical connector is electrically connected to the first metal pad.

14. The semiconductor device of claim 9, further comprising:
a through via extending from the front-side to a back-side of the semiconductor substrate; and
an integrated circuit die attached to the semiconductor substrate and electrically connected to the through via.

15. A semiconductor device comprising:
a semiconductor substrate comprising a plurality of active devices at a front-side surface thereof;
an interconnect structure over the front-side surface of the semiconductor substrate, the interconnect structure comprising a plurality of metal lines and vias in a plurality of low-k dielectric layers, the plurality of metal lines and vias being electrically connected to the plurality of active devices;
a passivation layer over the interconnect structure; and
a seal ring extending along and encircling a periphery of the semiconductor device, the seal ring comprising a lower portion in the plurality of low-k dielectric layers and an upper portion embedded in the passivation layer and electrically connected to the lower portion, the lower portion and the upper portion being electrically insulated from the plurality of metal lines and vias and from the plurality of active devices, wherein the upper portion has a stair-step cross-sectional profile comprising a first step proximal to the lower portion and a second step distal from the lower portion.

16. The semiconductor device of claim 15, wherein the second step is wider than the first step, and wherein the second step is laterally offset from the first step in a direction toward a sidewall of the semiconductor device.

17. The semiconductor device of claim 15, wherein the second step is laterally offset from the first step in a direction away from a sidewall of the semiconductor device.

18. The semiconductor device of claim 15, wherein a dielectric constant of the passivation layer is greater than a dielectric constant of the plurality of low-k dielectric layers.

19. The semiconductor device of claim 15, further comprising an additional passivation layer over the passivation layer, wherein the first step is embedded in the passivation layer and the additional passivation layer, and wherein the second step is embedded in the additional passivation layer and interfaces with a surface of the passivation layer.

20. The semiconductor device of claim 19, further comprising a metal pad embedded in the passivation layer and the additional passivation layer, wherein the metal pad is electrically connected to the interconnect structure, wherein the metal pad is electrically insulated from the seal ring, and wherein the metal pad has a cross-sectional profile different from the stair-step cross-sectional profile of the upper portion of the seal ring.
